(19) United States
(12) Patent Application Publication
(10) Pub. No.: US 2006/0131758 A1
(43) Pub. Date: Jun. 22, 2006

(54) Anchored non-solder mask defined ball pad

(75) Inventor: Christine Ha Dao, Lewisville, TX (US)

Correspondence Address: STMICROELECTRONICS, INC, MAIL STATION 2346, 1310 ELECTRONICS DRIVE, CARROLLTON, TX, 75006, US

(73) Assignee: STMicroelectronics, Inc.

(21) Appl. No.: 11/022,218

(22) Filed: Dec. 22, 2004

(51) Int. Cl. H01L 23/48

(52) U.S. Cl. 257/779

(57) ABSTRACT

A ball grid pad for connecting a ball grid array package to a printed circuit board includes a circular pad area adhered on a ball grid connection surface. A solder mask on the ball grid connection surface has an opening surrounding and spaced apart from the circular pad area. The ball pad includes an anchor trace on the ball grid connection surface wherein the ball pad conductor material extends radially from the edge of the circular pad area to a terminating point beyond the opening of the solder mask so that a portion of the anchor trace is covered by the solder mask. The ball grid connection surface may be an integrated circuit package substrate or a printed circuit board surface.

### BACKGROUND OF THE INVENTION

1. Field of the Invention

The present invention relates generally to integrated circuits, and more specifically to designs for integrated circuits having packages and substrates using ball grid array packaging. Still more specifically, the present invention relates to an improved non-solder mask defined ball pad for an integrated circuit substrate and printed circuit board that uses a ball grid array.

2. Description of the Prior Art

Many electronic products, such as computers, radios, and televisions, contain electronic components and integrated circuits that are mounted to printed circuit boards. To make a functional circuit, these electronic components are electrically connected to each other by metal traces that are printed like wires on the circuit board. Such “printed wires” lead from a connection point on one component to a connection point on another component.

Electrical components are frequently mounted to the circuit board by a technique called “surface mounting.” For example, FIG. 1 shows integrated circuit 20 that is surface mounted to printed circuit board 22. A surface mounted component, such as integrated circuit 20, is connected and fastened to the circuit board by solder joints between connection points on the electrical component package and corresponding electrical connection points that are printed on the circuit board. The electrical connection points are called pads, or lands. Thus, the component is electrically and mechanically connected by solder that has been melted to the metal pad on the circuit board and the metal pad on the component package.

When an electrical component has a large number of inputs and outputs, the component package must have a large number of pads to accommodate the connections. And because there is a great emphasis placed on reducing the size of electronic products, and hence reducing the size of components inside the products, the space between the many pads is made increasingly smaller. With small pads and tight spacing, the precision of the placement and alignment of the component on the circuit board becomes critical. The pads on the component must align precisely with the pads on the board in order to make the strongest and most reliable connection.

To make it easier to align the components with the printed circuit board, engineers may use a ball grid array (BGA) package. Some of the advantages of BGA packaging over other new technologies are that BGAs offer significantly more misalignment tolerance, less susceptibility to co-planarity issues, and easier printed circuit board signal routing under the BGA package. BGAs can also be supported with existing placement and assembly equipment.

In FIG. 1, integrated circuit 20 uses a ball grid array package. As shown, ball grid array 24 includes a plurality of spaced apart solder balls 26 located between a bottom surface of integrated circuit substrate 28 and the surface of printed circuit board 22.

There are generally two types of solder pad patterns used for surface mount packages: solder mask defined (SMD) pads and non-solder mask defined (NSMD) pads. As shown in FIG. 3, SMD pads have solder mask openings that are smaller than the pad. As shown in FIG. 5, NSMD pads have solder mask openings larger than the pad.

FIG. 3 is a plan view of a prior art solder mask defined ball pad for a ball grid array. As illustrated, ball pad 50 is adhered to the surface of substrate 28. Substrate 28 is typically an organic substrate, which is used for routing electrical signals and power between pads on a chip die and solder ball pads on the bottom of the integrated circuit package. Ball pad 50 is connected to via pad 80 by electrical connection trace 84. Ball pad 50, via pad 80, and electrical connection trace 84 are all made and formed of conductor material 38, which is preferably copper or some other similar conducting metal which may be formed by known photo etching techniques. Via pad 80 surrounds via 82, which is a plated-through hole plated with conductor material 38 to transfer electrical signals to another conductor layer within or on substrate 28.

Note that ball pad 50 in FIG. 3 is a relatively large ball pad that is overlapped by solder mask 74. Circular solder mask opening 76 defines an area that is open to conductor 38 to provide access to a metal area of ball pad 50 for a solder connection with a solder ball. Note that in FIG. 3 solder mask 74 is depicted with a right-slanted, dashed, hatched pattern, and conductor 38 is illustrated with a left-slanted hatch at pattern. In areas where solder mask 74 overlaps conductor 38, both patterns are shown creating a cross-hated pattern.

With reference to FIG. 4, there is depicted a section view taken along line IV-IV, of the solder mask defined ball grid array pad that is shown in FIG. 3. As depicted, ball pad 50, which is made of conductor material 38, is adhered to substrate 28. Solder mask 74 is applied over substrate 28 and overlaps or covers portions of ball pad 50. Opening 76 exposes a portion of ball pad 50 and defines the ball pad where solder is allowed to connect a solder ball to ball pad 50.

With reference now to FIG. 5, there is depicted a plan view of a non-solder mask defined ball pad, which is known in the prior art. As illustrated, ball pad 52 is adhered to the surface of substrate 28. Ball pad 52 may be connected to via pad 80 by electrical connection trace 84, where is formed of conductor material 38 and adhered to the surface of substrate 28. Note that in the non-solder mask defined ball pad, solder mask opening 76 is larger than ball pad 52 so that solder mask opening 76 does not touch or overlap ball pad 52. The larger opening of solder mask opening 76 leaves a gap 78 between solder mask 74 and ball pad 52, wherein gap 78 exposes the surface of substrate 28. Solder mask opening 76 is generally circular and concentric with the circular shape of ball pad 50, which leaves some portions of electrical connection trace 84 exposed and other portions covered with solder mask 74. As with FIG. 3, FIG. 5 includes a solid hatching pattern for illustrating conductor material 38, and a dashed hatching pattern to illustrate areas covered by solder mask 74. Cross hatched areas show conductor material 38 covered by solder mask 74.

FIG. 6 shows the sectional view of a non-solder mask defined ball pad, which view is taken along line VI-VI in FIG. 5. As illustrated, ball pad 52, which is made of conductor material 38, is adhered to the surface of substrate 28. Solder mask 74 is also applied to the surface of substrate 28, and has an opening 76 that surrounds ball pad 52 and leaves gap 78 between solder mask 74 and ball pad 52.

Solder mask defined pads are stronger than non-solder mask defined pads for two reasons. First, the solder mask overlap provides extra strength to the adhesion bond between the copper pad and the substrate laminate. Second, because the copper needs to extend beyond the edge of the solder mask the actual copper pad area is larger. This provides additional copper surface to which the laminate can adhere. This added strength may be important in cases where the pad-to-PCB attachment could fail due to board flexing or excessive temperature cycling.

The drawback of the SMD pad is a material mismatch at the junction between the solder ball, the copper pad edge, and the solder mask edge. This junction of various materials is weak, which may cause the solder ball to crack under stress, particularly during temperature cycling. In contrast, the NSMD pad may provide more surface area for the ball to adhere to the pad, wherein the melted solder flows and wraps around the side of the pad. Also, the NSMD pad can also produce a more uniform hot air solder leveled surface finish.

Therefore, it should be apparent to those persons skilled in the art that a need exists for an improved ball pad for surface mounting ball grid array packages where in the pad has the adherence strength advantages of the solder mask defined pad and the solder joint strength of the non-solder mask defined pad.

### BRIEF DESCRIPTION OF THE DRAWINGS

For a more complete understanding of the present invention, and the advantages thereof, reference is now made to the following descriptions taken in conjunction with the accompanying drawings, in which like numbers designate like parts, and in which:

FIG. 1 is an elevation view of an integrated circuit ball grid array package mounted on a printed circuit board, which is know in the prior art;

FIG. 2 is a partial section view of an integrated circuit ball grid array package, which is known in the prior art;

FIG. 3 is a plan view of a solder mask defined ball pad for a ball grid array, which is known in the prior art;

FIG. 4 is a section view of the solder mask defined ball grid array pad shown in FIG. 3;

FIG. 5 is a plan view of a non-solder mask defined ball pad, which is known in the prior art;

FIG. 6 is a section view of the non-solder mask defined ball pad shown in FIG. 5;

FIG. 7 is a plan view of a non-solder mask defined ball pad having anchor traces in accordance with the present invention; and

FIG. 8 is an alternate plan view of the non-solder mask defined ball pad shown in FIG. 7 in accordance with the present invention.

### DESCRIPTION OF THE PREFERRED EMBODIMENTS

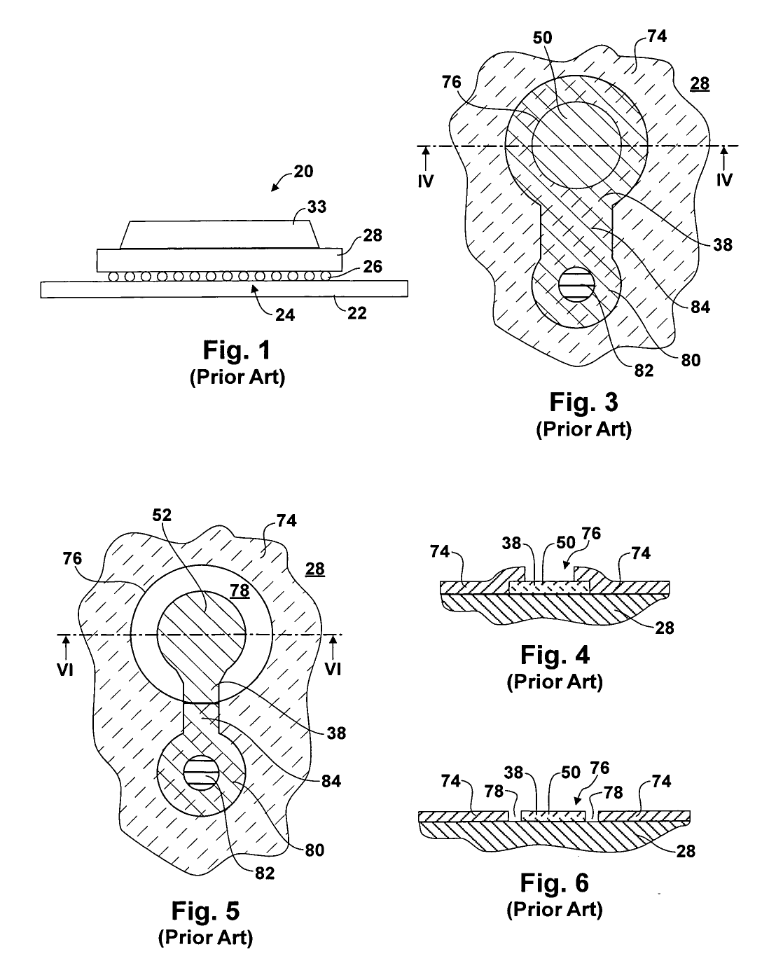

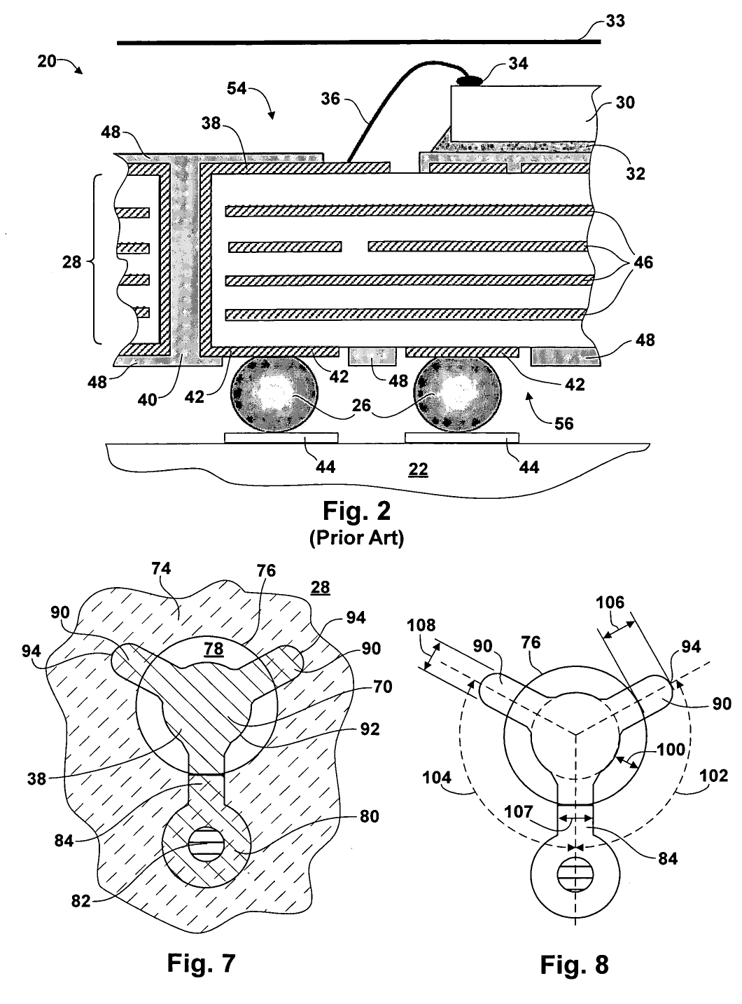

With reference now to the drawings, and in particular with reference to FIG. 2, there is depicted a partial section view of integrated circuit 20, which is shown in FIG. 1. As illustrated, integrated circuit 20 includes substrate 28 and integrated circuit die 30, which is mounted to substrate 28 by epoxy 32. Die 30 is covered and protected by cover 33 (which is also shown in FIG. 1). The surface of substrate 28 to which die 30 is mounted, may be referred to as “die mounting surface” 54.

An electrical connection is made to die 30 at bond 34 using wire 36. Wire 36 carries signals, or power, to and from die 30 and conductor 38. Conductor 38 is adhered to, and is a part of, substrate 28. Integrated circuit signals pass along conductor 38, and, in the example illustrated, through via 40 to the opposite side of substrate 28 where substrate pads 42 are formed. The surface on which pads 42 are formed may be referred to as a “ball grid connection surface” 56.

Solder balls 26 may be attached to substrate pads 42 and reflowed to create the BGA package. During assembly of integrated circuit 20, solder ball 26 melts to cover the surface of the exposed metal pad 42, and surface tension of the melted solder maintains the generally spherical shape of the ball.

When integrated circuit 20 is assembled to printed circuit board 22, solder paste is screen printed on PCB pads 44. The integrated circuit BGA package 20 is then aligned with the PCB so that substrate pads 42 are aligned with printed circuit board pads 44, and solder balls 26 make a connection between substrate pads 42 and printed circuit board pads 44. Thereafter, solder is reflowed a second time, and solder balls 26 may melt again during this PCB assembly process. This creates more of a bulging column of solder, where the top and bottom of the ball 26 covers the surface of each pad 42 and 44. When the melted solder cools, the electrical and mechanical connection is completed.

In some applications, solder balls 26 that have a higher melting point than the solder paste are used. Such higher-melting-point balls may be used when a package is heavy enough to squash the melted solder ball during the second solder reflow. Still, solder balls 26 are attached to substrate 22 prior to the surface mounting of the integrated circuit 20. With a good solder reflow profile and correct PCB layout, the solder paste will reflow properly and form a meniscus encapsulating the solder ball.

Substrate 28 may be implemented with a plastic material called polyimide. A standard subtractive process may use a material similar to the core material in the build-up process. This material may be made of epoxy and fiberglass weave. Conductor material 38 is preferably metal, such as copper. Conductor 38 is adhered to the outer surfaces of substrate 28 and photo-etched to provide metal patterns for conductors and ball grid array pads for bonding. Substrate 28 may also include inner metal layers 46, which are imbedded in layers of substrate 28 in order to accommodate the dense routing of electrical conductors. Connection between layers may be accomplished by vias 40, which have plated-through conductors 38.

In order to confine melted solder to ball pads 42 and 44, substrate 28 may be coated with solder mask 48. Solder mask 48 may be used on both top and bottom surfaces of substrate 28, where, by convention used herein, solder balls 26 are in contact with pads 42 on the bottom surface of substrate 28. As shown in FIG. 2, solder mask 48 has openings around pads 42 and other places for making solder connections to solder balls 26 and connecting wire 36.

With reference now to FIG. 7, there is depicted a plan view of an improved non-solder mask defined ball pad in accordance with the present invention. As illustrated, ball pad 70 is formed of conductor 38 on a surface of ball pad grid substrate 28. Solder mask 74 is also selectively applied over areas of ball pad grid substrate 28 and conductors 38. Solder mask 28 has solder mask opening 76 centered over ball pad 70. Solder mask opening 76 is larger than ball pad 70 and surrounds ball pad 70, leaving gap 78 between the metal of ball pad 70 and solder mask 74.

Ball pad 70 is typically connected to via pad 80, which surrounds via 82, by electrical connection trace 84. Electrical connection traces 84 are traces or printed circuits that carry electrical power or signals.

According to an important aspect of the present invention, anchor trace 90 is formed of conductor 38 and is also adhered on ball pad grid substrate 28. Anchor trace 90 and extends radially from ball pad edge 92 to a terminating point 94 beyond solder mask opening 76, so that a portion of anchor trace 90 is covered by solder mask 74.

In a preferred embodiment, ball pad 70 is circular. Solder mask opening 76 is also circular and concentrically aligned with the center of ball pad 70. In one embodiment, solder mask opening 76 is preferably spaced apart from ball pad edge 92 by a distance large enough to ensure that ball pad 70 is exposed after factoring in manufacturing alignment errors and tolerances. In a preferred embodiment gap 78 typically 0.1 millimeters, with about 0.120 millimeters maximum and 0.060 millimeters minimum.

In alternative embodiments, ball pad 70 can be obround, oval, or ovoid. Obrounds are like rectangles that have been rounded to a semi-circle on the short sides. Similarly, mask opening 76 can be obround, oval, or ovoid.

Various measurements of the ball grid pad of the present invention are shown in more detail in FIG. 8. As depicted in FIG. 8, the measurement of gap 78 is shown at reference numeral 100. FIG. 8 also illustrates the angular position of anchor traces 90 with respect to electrical connection trace 84. In a preferred embodiment, angles 102 and 104 are equal, with a preferred angle of about 120 degrees. When angles 102 and 104 are equal, anchor traces 90 are symmetrically angularly spaced apart from electrical connection trace 84.

FIG. 8 also shows length 106 between solder mask opening 76 and anchor trace 90 terminating point 94. In preferred embodiments, length 106 is 0.075 millimeters for ball grid arrays having ball pitches of between 1.0-1.27 millimeters, and length 106 is 0.06 millimeters in a ball grid array having a ball pitch of 0.8 millimeters. Length 106 is the length of the portion of anchor trace 90 that is covered by solder mask 74. Anchor trace width 108 is preferably substantially equal to width 107 of electrical connection trace 84, which is typically 0.080 millimeters, and can range from about 0.050 millimeters to about 0.120 millimeters.

As may be seen in FIG. 7, portions of anchor traces 90 extending from ball pad 70 are covered by solder mask 74, which adds extra strength to solder pad 70 because anchor traces 90 and electrical connection trace 84 add additional conductor area 38 that is adhered to substrate 28, and a portion of the additional anchor trace conductor area is covered by solder mask 74, which provides additional strength in holding solder pad 70 on substrate 28. This is partly because solder mask 74 adheres to substrate 28 better than conductor material 38. Therefore, persons skilled in the art should recognize that the ball pad configuration shown in FIGS. 7 and 8 provides the advantage of additional strength in the ball pad and in adhering to the ball grid connection surface, while still maintaining the advantages of NSMD ball pads.

When solder is allowed to reflow over the anchored ball pad of the present invention, solder may form an extended meniscus along portions of anchor traces 90 and electrical connection trace 84. Such extensions to the solder meniscus may provide additional strength to the solder connection.

In a preferred embodiment of the present invention, an anchored ball pad includes two anchor traces 90. However, anchored ball pads may include one, three or more anchor traces 90.

While the description of the present invention has focused on anchored ball pad configurations on the bottom of an integrated circuit substrate, the anchored ball pad pattern may also be applied to the surfaced of a printed circuit board. Thus, ball pads with mirror images may be uses, for example, as substrate pads 42 and as printed circuit board pads 44, as shown in the relationship between such pads in FIG. 2. This means that the bottom of substrate 28 and the top of circuit board 22 may both be referred to as a “ball grid connection surface” where anchored ball pads of the present invention may be formed.

The foregoing description of a preferred embodiment of the invention has been presented for the purpose of illustration and description. It is not intended to be exhaustive or to limit the invention to the precise form disclosed. Obvious modifications or variations are possible in light of the above teachings. The embodiment was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

In alternative embodiments of the present invention, anchor traces 90 may be configured differently at terminating point 94. As shown in FIGS. 7 and 8, terminating point 94 is rounded. Alternatively, another shape may be formed at terminating point 94, such as, for example, a circle, which may be similar in size and shape to via pad 80. Such alternative shapes at terminating point 94 may provide additional ball pad strength.

What is claimed is:

1. A ball grid array substrate for a semiconductor device package comprising:
a ball pad on a surface of the ball grid array substrate;
a solder mask on the surface of the ball grid array substrate, wherein the solder mask has a solder mask opening that is larger than the ball pad and surrounds the ball pad; and
an anchor trace on the surface of the ball grid array substrate that extends radially from the edge of the ball pad to a terminating point beyond the opening of the solder mask so that a portion of the anchor trace is covered by the solder mask.

2. The ball grid array substrate according to claim 1 wherein a ball pad shape is a shape selected from the group of shapes consisting of a circle, an obround, and an ovoid.

3. The ball grid array substrate according to claim 1 wherein the solder mask opening has a shape selected from the group of shapes consisting of a circle, an obround, and an ovoid.

4. The ball grid array substrate according to claim 1 wherein the solder mask opening is spaced apart from the ball pad by a distance of from 0.060 millimeters to 0.120 millimeters.

5. The ball grid array substrate according to claim 1 further including two anchor traces and an electrical connection trace on the surface of the ball grid array substrate that each extend radially from the edge of the ball pad, wherein the two anchor traces are symmetrically angularly spaced from the electrical connection trace and extend to a terminating point beyond the opening of the solder mask so that a portion of the anchor trace is covered by the solder mask.

6. The ball grid array substrate according to claim 1 further including an electrical connection trace that extends radially from the edge of the ball pad to a point beyond the opening of the solder mask.

7. The ball grid array substrate according to claim 6 wherein the electrical connection trace has an electrical connection trace width, and wherein a width of the anchor trace is substantially equal to the electrical connection trace width.

8. A ball grid pad for connecting a ball grid array package to a printed circuit board, the ball grid pad comprising:
a circular pad area on a ball grid connection surface;
a solder mask on the ball grid connection surface, wherein the solder mask has an opening surrounding and spaced apart from the circular pad area; and
an anchor trace on the ball grid connection surface that extends radially from the edge of the circular pad area to a terminating point beyond the opening of the solder mask so that a portion of the anchor trace is covered by the solder mask.

9. The ball grid pad according to claim 8 wherein the solder mask is spaced apart from the circular pad area by a distance ranging from 0.060 millimeters to 0.120 millimeters.

10. The ball grid pad according to claim 8 further including an electrical connection trace on the ball grid connection surface extending radially from the edge of the circular pad area beyond the opening of the solder mask.

11. The ball grid pad according to claim 10 wherein the electrical connection trace has an electrical connection trace width, and wherein a width of the anchor trace is substantially equal to the electrical connection trace width.

12. The ball grid pad according to claim 8 further including two anchor traces and an electrical connection trace on the ball grid connection surface, each extending radially from the edge of the ball pad, wherein the two anchor traces are symmetrically angularly spaced from the electrical connection trace and extend to a terminating point beyond the opening of the solder mask, wherein a portion of the anchor trace is covered by the solder mask.

13. The ball grid pad according to claim 8 wherein the portion of the anchor trace covered by the solder mask extends from the solder mask opening to the terminating point, which portion has a length ranging from 0.060 millimeters to 0.075 millimeters.

14. The ball grid pad according to claim 8 wherein the ball grid connection surface is a surface on a substrate of the ball grid array package.

15. The ball grid pad according to claim 8 wherein the ball grid connection surface is a surface on the printed circuit board.

16. An integrated circuit in a ball grid array package, the integrated circuit comprising:
a ball grid array package substrate having a die mounting surface and an opposing ball grid connection surface;
an integrated circuit die mounted on the die mounting surface and electrically connected to a plurality of conductors on the ball grid array package substrate;
a circular pad area on the ball grid connection surface, wherein the pad area is electrically connected to one of the plurality of conductors;
a solder mask on the ball grid connection surface, wherein the solder mask has an opening surrounding and spaced apart from the circular pad area; and
an anchor trace on the ball grid connection surface that extends radially from the edge of the circular pad area to a terminating point beyond the opening of the solder mask so that a portion of the anchor trace is covered by the solder mask.

17. The ball grid pad according to claim 16 further including an electrical connection trace on the ball grid connection surface extending radially from the edge of the circular pad area beyond the opening of the solder mask.

18. The ball grid pad according to claim 17 wherein the electrical connection trace has an electrical connection trace width, and wherein a width of the anchor trace is substantially equal to the electrical connection trace width.

19. The ball grid pad according to claim 16 further including two anchor traces and an electrical connection trace on the ball grid connection surface, each extending radially from the edge of the ball pad, wherein the two anchor traces are symmetrically angularly spaced from the electrical connection trace and extend to a terminating point beyond the opening of the solder mask, wherein a portion of the anchor trace is covered by the solder mask.

20. The ball grid pad according to claim 16 wherein the portion of the anchor trace covered by the solder mask extends from the solder mask opening to the terminating point, which portion has a length ranging from 0.060 millimeters to 0.075 millimeters.
